(19) United States
(12) Patent Application Publication
(10) Pub. No.: US 2009/0196430 A1
(43) Pub. Date: Aug. 6, 2009

(54) POWER SUPPLY PROTECTION DEVICE WITH SOUND RECEIVING FUNCTION

(75) Inventors: Yu-Lung Lee, Nanjhuang Township (TW); Ming-Chou Kuo, Taipei City (TW)

Correspondence Address: NIKOLAI & MERSEREAU, P.A., 900 SECOND AVENUE SOUTH, SUITE 820, MINNEAPOLIS, MN, 55402, US

(73) Assignee: Powertech Industrial Co., Ltd., Chung Ho City (TW)

(21) Appl. No.: 12/140,511

(22) Filed: Jun. 17, 2008

(30) Foreign Application Priority Data
Feb. 1, 2008 (TW) 97104061

(51) Int. Cl. H03G 11/00

(52) U.S. Cl. 381/55

(57) ABSTRACT

A power supply protection device with sound receiving function includes a casing; a sound processing unit, mounted inside the casing and used to receive a sound frequency; and a power source unit, used to control a power source input to provide the sound processing unit with power. The power source unit includes a circuit protection unit and at least one electric socket on the casing. Thereby, the power supply protection device offers multiple functions such as sound receiving and power protection.

### BACKGROUND OF THE INVENTION

1. Field of the Invention

The invention generally relates to a power supply protection device, and particularly to a power supply protection device with superior-quality power supply and sound receiving performance.

2. Description of the Related Art

Electric power is essential to the development of society. Domestic appliances, illuminations, commercial equipment and other electric industries need electricity. Howsoever, the quality of electric power may sometimes be insufficient due to various factors like e.g. transport over long distances. Therefore, stable and low-noise electricity has been a critical issue for future development.

In general, many semiconductor devices have been used as control circuits in electric products for traditional or high-tech industries. While semiconductor devices contribute to decrease the volume of electric products, the resistance of the electric products to noise in the electricity power supplied to them is weak due to their inherent properties. Furthermore, as the density and number of devices within the products increase, low power consumption of each device is very important. Therefore, low operation voltage and small amplitude are the trend of design. However, the higher the operation voltage, the easier a device is affected by noise. Noise may arise from various sources such as signal coupling or cross-talking, interfering with two neighboring signals, or electromagnetic radiation. The greatest influence among those is the noise from the electricity. Therefore, how to protect the electric appliances from being damaged due to surge waves and prevent fire accidents due to short-circuit are key-issues to be resolved.

Sound produced by the equipment may also be affected by noise from electricity. For example, audio equipment will have large alternative noise if its internal power filter is not so good.

Therefore, the inventors have intensively studied and finally provide a power supply protection device which significantly reduces noise for power supply while also offering a sound receiving function.

### SUMMARY OF THE INVENTION

It is an object of the invention to provide a power supply protection device with sound receiving function, which outputs highly pure power and offers sound receiving function.

In order to achieve the above and other objectives, the power supply protection device of the invention includes a casing; a sound processing unit, mounted inside the casing and used to receive a sound frequency; and a power source unit, used to control a power source input to provide the sound processing unit with power. The power source unit includes a circuit protection unit and at least one electric socket on the casing,

The invention offers the electric socket for an external electric appliance to plug and also provide improved sound receiving performance.

To provide a further understanding of the invention, the following detailed description illustrates embodiments and examples of the invention, this detailed description being provided only for illustration of the invention.

### BRIEF DESCRIPTION OF THE DRAWINGS

FIG. 1 is a functional block diagram of a power supply protection device with sound receiving function according to one embodiment of the invention.

FIG. 2 is a schematic view of a power supply protection device with sound receiving function according to a first embodiment of the invention.

FIG. 3 is a schematic view of a power supply protection device with sound receiving function according to a second embodiment of the invention.

FIG. 4 is a schematic view of a power supply protection device with sound receiving function according to a third embodiment of the invention.

### DETAILED DESCRIPTION OF T HE EMBODIMENTS

Wherever possible in the following description, like reference numerals will refer to like elements and parts unless otherwise illustrated.

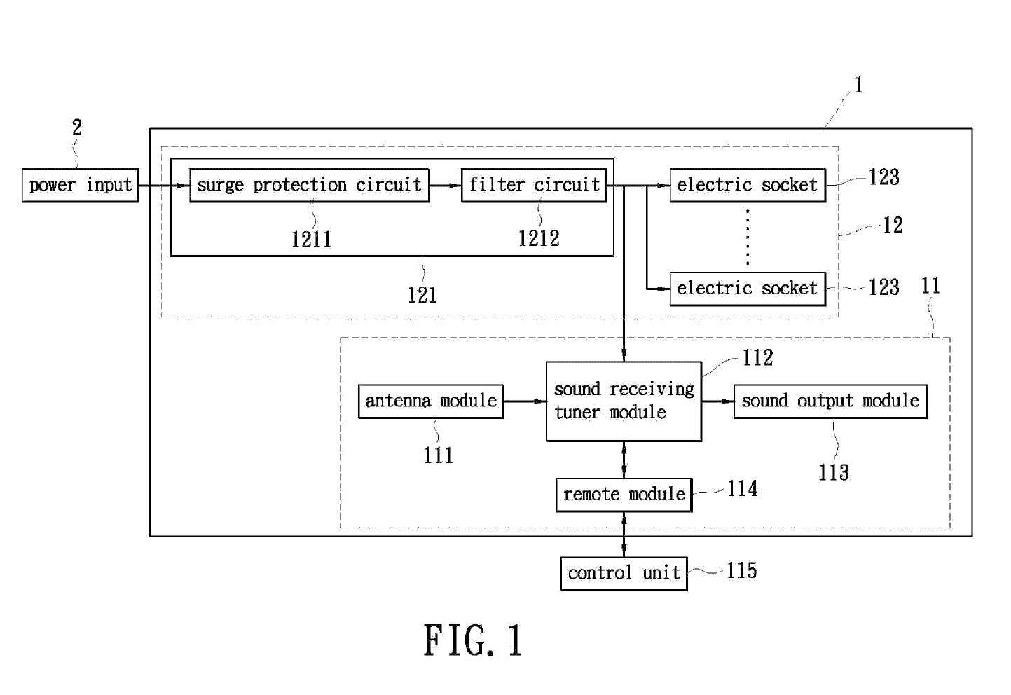

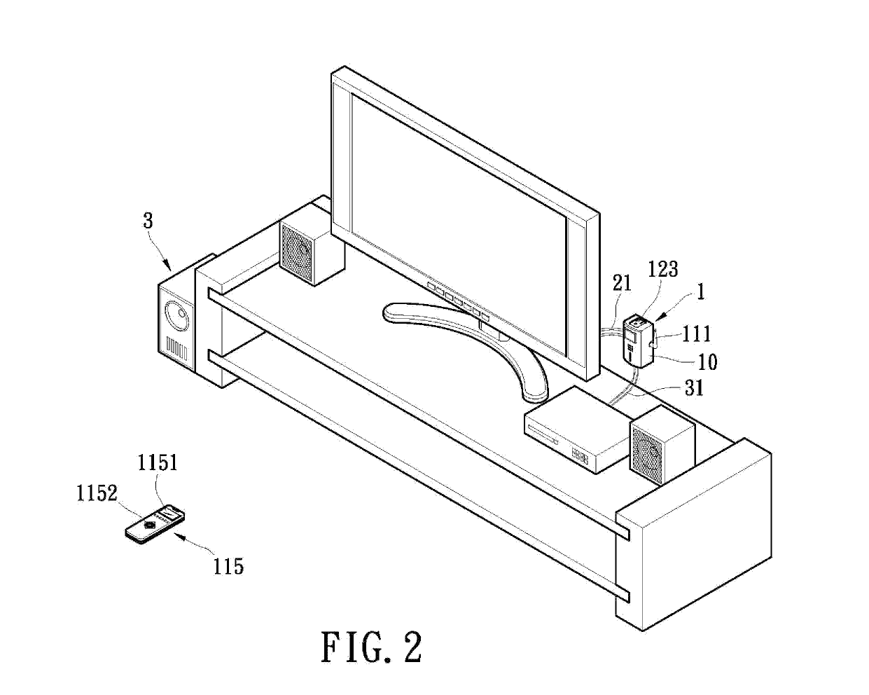

Referring to FIG. 1, a power supply protection device I with sound receiving function provides other electric appliances with power supply as shown in FIG. 2 through FIG. 4, while receiving a sound frequency such as a digital broadcasting or an analogue broadcasting signals. The power supply protection device 1 with sound receiving function includes a casing 10, a sound processing Unit 11 and a power supply unit 12. The power supply unit 12 is mounted inside the casing 10 to control a power input 2 to be the power for the sound processing unit 11. The power supply 12 further includes at least one electric socket 123 on the casing 10 and a circuit protection unit 121. The invention provides the power supply protection device 1 with a sound receiving function, in which not only at least one electric socket 123 offers safe and convenient use of power supply for other appliances but also a sound frequency can be received for broadcasting. The power supply unit 12 has a circuit protection unit 121 to output a high-purity power supply to the sound processing unit 11 so that higher sound receiving quality can be ensured.

In the power supply protection device 1 with the sound receiving function according to one embodiment of the invention, the power supply unit 12 is connected to a power input 2. The power input 2 outputs the power to the sound processing unit 1. For more proper power supply, the power supply unit 12 of the power supply protection device 1 has at least one power supply socket 123 on the casing 10 of the power supply protection device 1 so that the user call directly insert a plug of one of other appliances into the power supply socket 123 to offer required electric power. The power supply unit 12 further has a circuit protection unit 121 to protect an external appliance of the power source socket 123 and the sound processing unit 11.

The circuit protection unit 121 at least includes a surge protection circuit 1211 and a filter circuit 1212. The surge protection circuit 1211 can be a surge absorber which can be a circuit protection element an functions to limit and absorb any abnormal voltage or thunder surge wave so as to protect the wiring from being disturbed or damaged by thunder. The filter circuit 1212 can be a power supply filter which can be made of inductive or capacitive material Capacitors and inductors are combined to form a low pass filter which allows only signals at frequencies of 60 Hz or lower to pass and blocks signals at frequencies of higher than 60 Hz which are also called noise, thereby the noise being removed. Supply of highly pure power contributes to superior circuit protection because unstable situations such as overdue voltage, overdue current, low voltage and overload can be avoided, and also prevent accidents caused by improper use of domestic electricity or unstable power supply. Automatic load detection is further provided for automatic control of power output to prevent the external appliance or the sound processing unit 11 from being damaged by the noise. Similarly, the power supply unit 12 can be protected from any interference such as peak voltage, voltage noise and static electricity. Output of the purified and stable power allows the sound processing unit 11 to output improved sound effect.

The sound processing unit 11 is mounted inside the casing 10 to receive the above sound frequency. The sound processing unit 11 includes an antenna module 111 used to receive the sound frequency; a sound receiving tuner module 112 coupled to the antenna module 111; and a sound output module 113 coupled to the sound receiving tuner module 112. The sound processing unit 11 functions to receive and output a sound source sign al. The sound processing unit 11 uses the antenna module 111 to receive a sound frequency. The sound frequency can be, but not limited to, digital audio broadcasting (DAB), high-definition radio (HAD Radio), XM Satellite radio or analogue radio such as AM signals or FM signal.

On the other hand, the power supply protection device 1 has a general sound frequency receiving function. Here below illustrates the power supply protection device of the invention applied to digital sound receiving. The power supply protection device 1 includes a sound processing unit 1I1 using an antenna module 111 to receive digital sound frequency of different channels. The antenna module 111 can be an external antenna or an internal antenna, or has an internet entrance. The format of the antenna module 111 of the invention is not particularly limited. The received signal must pass the sound receiving tuner module 112 before being output. The sound receiving tuner module 112 at least includes an analogue front-end chip and a digital base-band processor. The analogue front-end chip is used for front-end signal analysis, and the digital base-end processor is used for processing back-end data. A digital signal processor (DSP) and a digital IF tuner are essential to the sound receiving tuner module 112.

After the sound source signal is analyzed by the sound receiving tuner module 112, the signal is output via the sound output module 113. The sound output module 113 is connected to a sound system 3 such as audio-in terminal of an amplifier so that the sound can be output via the sound system 3, as shown in FIG, 3. The sound processing unit 11 further includes a remote module, 114 of the sound receiving tuner module 112. The remote module 114 is used to receive signals from a control unit 115. That is, the user controls the control keys 1152 of the control unit 115 to emit control signals for control sound volume, election of broadcasting channels. On the other hand, the control unit 115 receives signals emitted from the remote nodule 114 and displays those signals on a display module 1151. For example, current sound frequency is displayed on the display module 1151 for user's convenience. However, this invention is not particuarly limited to the application of digital sound receiving.

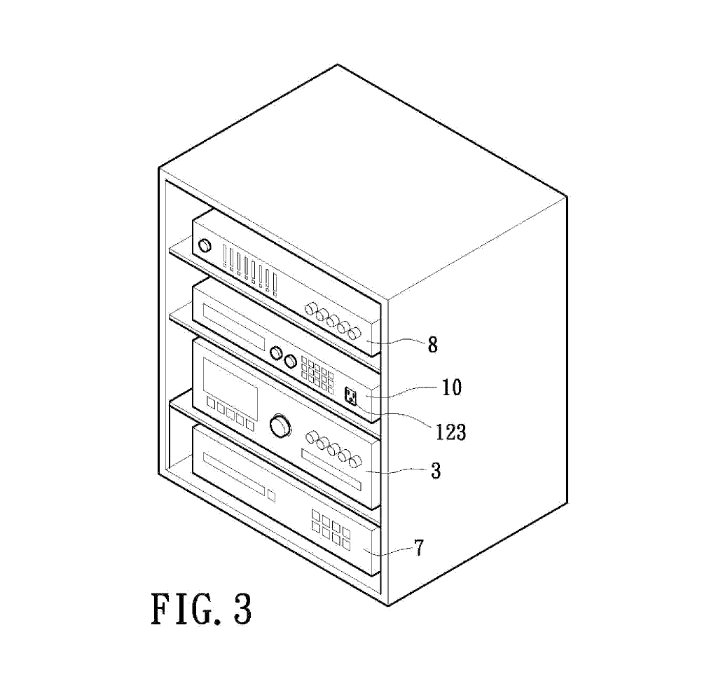

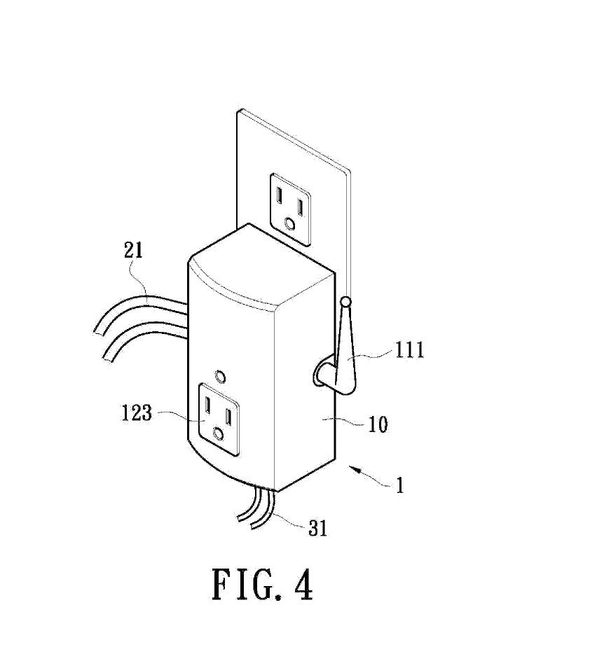

In order to meet various needs for users, the power supply protection device 1 can have different appearances. For example the power supply protection device 1 as shown in FIG. 2 is in shape of a rectangular solid. i.e. the casing 10 of the power supply protection device 1 is made in the format of a rectangular solid. The power supply protection device 1 is connected to a power supply via an electric power line, and connected to the sound system 3 via a sound signal line 31. FIG. 3 is a schematic view of a power supply protection device with sound receiving function according a second embodiment of the invention. The casing 10 of the power supply protection device 1 is mounted as a rack in a rack where it can be placed and cooperate with the sound system 3 such as an amplifiers an equalizer 8, and a multimedia player 7 (such as DVD player) to output digital sound. FIG. 4 is a schematic view of a power supply protection device according to a third embodiment of the invention. The casing 10 of the power supply protection device 1 is in shape of wall tap. I.e., the casing of the power supply protection device 1 can be varied according to the environments and use conditions. The shape of the casing is not particularly limited to those described above.

The power supply protection device can be integrated with more functions. For example, the power supply protection device 1 further includes memory cards such as interfaces of Flash Memory or MMC/SD Memory Stick for digitally recording and increasing the radio frequencies to 384 kbps so as to broaden the application scope of digital broadcasting. Alternatively, built-in FM sound receiving and the support of Transport Protocol Experts Group (TPEG) help the users to retrieve updated traffic information and timely time the digital broadcast to catch tip real-time news or urgent events. Meanwhile, the power supply protection device 1 further offers TII (Transmitter Identification Information) which indicates the user's current location. In addition to the above built-in memory interface, the power supply protection device 1 also has an USB interface of 12 Mbps used as a connector for an external plug-in digital radio, for example, to a host computer. The power supply protection device further supports to decode various sound signals such as PCM, MP3 and WMA sources.

In light of the above, the invention provides the following advantages:
1. The power supply protection device of the invention offers more applications. It can be connected to the power of the external electric appliance while receive sounds, which adds value in use for the users.
2. The power supply protection device has a circuit protection unit 121 to provide highly pure power so that the sound processing unit 11 and the external electric appliance will not be damaged because of unstable domestic electricity.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

1. A power supply protection device with sound receiving function, comprising:
a casing;
a sound processing unit, mounted inside the casing and used to receive a sound frequency; and
a power source unit used to control a power source input to provide the sound processing unit with power, wherein the power source unit comprises a circuit protection unit and at least one electric socket on the casing.

2. The power supply protection device with sound receiving function of claim 1, wherein the circuit protection unit comprises at least one surge protection circuit and a filter circuit.

3. The power supply protection device with sound receiving function of claim 1, wherein the sound frequency is a digital audio broadcasting (DAB), a high-definition radio (HD radio) or XM satellite radio.

4. The power supply protection device with sound receiving function of claim 1 wherein the sound processing unit comprises:
an antenna module, used to receive the sound frequency;
a sound receiving tuner module, coupled to the antenna module; and
a sound output module, coupled to the sound receiving tuner module.

5. The power supply protection device with sound receiving function of claim 4, wherein the sound output module is connected to a sound system.

6. The power supply protection device with sound receiving function of claim 5, wherein the sound processing unit further comprises a remote module connected to the sound receiving tuner module.

7. The power supply protection device with sound receiving function of claim 6, wherein the remote module receives signals of a control unit.

8. The power supply protection device with sound receiving function of claim 6, wherein the remote module emits a signal to a control unit.

9. The power supply protection device with sound receiving function of claim 1, wherein the casing has the shape of a rectangular solid, a wall tap or is mounted in a rack.
